(19) United States
(12) Patent Application Publication
(10) Pub. No.: US 2016/0329342 A1
(43) Pub. Date: Nov. 10, 2016

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Hauk HAN, Hwaseong-si (KR); Yeon-Sil SOHN, Yongin-si (KR)

(21) Appl. No.: 15/096,413

(22) Filed: Apr. 12, 2016

(30) Foreign Application Priority Data
May 4, 2015 (KR) 10-2015-0062608

(51) Int. Cl. H01L 27/115; H01L 29/06; H01L 29/51; H01L 29/792; H01L 29/49

(52) U.S. Cl. CPC H01L 27/11568; H01L 29/792; H01L 29/4941; H01L 29/513; H01L 29/0649

(57) ABSTRACT

A semiconductor device includes a charge storage pattern on a substrate, a blocking insulating pattern on the charge storage pattern, and a control gate structure on the blocking insulating pattern, the control gate structure having a metal electrode pattern, and an oxidation prevention pattern on the metal electrode pattern, the oxidation prevention pattern including a metallic nitride.

### CROSS-REFERENCE TO RELATED APPLICATION

This application claims priority under 35 U.S.C. §119 of Korean Patent Application No. 10-2015-0062608, filed on May 4, 2015, the entire contents of which are hereby incorporated by reference.

### BACKGROUND

Example embodiments relate to a semiconductor device, and more particularly, to a semiconductor device including a metal electrode.

A field effect transistor (hereinafter it is referred to as a transistor) is one of the elements constituting a semiconductor device. The transistor includes a source and a drain that are formed to be spaced apart from each other on a semiconductor substrate, and a gate covering a channel between the source and the drain. The source and the drain are formed by implanting dopants into the semiconductor substrate and the gate is insulated from the channel by a gate insulating layer disposed between the semiconductor substrate and the gate. The transistor is widely being used as a single element constituting a memory device, a switching device, and/or a logical circuit in a semiconductor device.

Recently, high-speed semiconductor devices have been demanded. On the contrary, sizes of transistors have been reduced as semiconductor devices have been highly integrated. However, operation speeds of semiconductor devices may be lowered by various factors such as fine sizes of transistors.

### SUMMARY

Example Embodiments provide a semiconductor device. In one aspect, a semiconductor device may include a charge storage pattern on a substrate, a blocking insulating pattern on the charge storage pattern, and a control gate structure on the blocking insulating pattern. The control gate structure may include a metal electrode pattern, and an oxidation prevention pattern provided on the metal electrode pattern and including a metallic nitride.

In some example embodiments, the oxidation prevention pattern may include at least one of titanium nitride, tungsten nitride and tantalum nitride.

In some example embodiments, a composition ratio of nitrogen included in the oxidation prevention pattern may range from 48 at % to 52 at %.

In some example embodiments, the metal electrode pattern may include tungsten.

In some example embodiments, the semiconductor device may further include a capping pattern on the control gate structure. The capping pattern may include silicon oxide.

In some example embodiments, the capping pattern may be in contact with the oxidation prevention pattern.

In some example embodiments, the control gate structure may further include a poly-crystalline silicon pattern between the metal electrode pattern and the blocking insulating pattern, and a barrier metal pattern between the metal electrode pattern and the poly-crystalline silicon pattern.

In some example embodiments, a thickness of the oxidation prevention pattern may be smaller than a thickness of the metal electrode pattern.

In some example embodiments, the semiconductor device may further include a tunneling insulating pattern disposed between the substrate and the charge storage pattern.

In some example embodiments, the oxidation prevention pattern may be in contact with the metal electrode pattern.

In another aspect, a semiconductor device may include a substrate having active regions which are defined by device isolation patterns extending in a first direction and are spaced apart from one another along a second direction crossing the first direction, a charge storage pattern disposed on at least one of the active regions, a blocking insulating pattern extending in the second direction to cover the charge storage pattern, and a control gate structure disposed on the blocking insulating pattern to extend in the second direction. The control gate structure may include a metal electrode pattern, and an oxidation prevention pattern provided on the metal electrode pattern and including a metallic nitride.

In some example embodiments, the oxidation prevention pattern may include at least one of titanium nitride, tungsten nitride and tantalum nitride.

In some example embodiments, a composition ratio of nitrogen included in the oxidation prevention pattern may range from 48 at % to 52 at %.

In some example embodiments, the semiconductor device may further include a capping pattern disposed on the control gate structure to extend in the second direction. The capping pattern may include silicon oxide.

In some example embodiments, the capping pattern may be in contact with the oxidation prevention pattern.

In some example embodiments, the control gate structure may further include a poly-crystalline silicon pattern between the metal electrode pattern and the blocking insulating pattern, and a barrier metal pattern between the metal electrode pattern and the poly-crystalline silicon pattern.

In some example embodiments, the charge storage pattern may include a plurality of charge storage patterns which are disposed on respective ones of a plurality of the active regions and arranged in the first direction. Top surfaces of the device isolation patterns may be exposed between the charge storage patterns. The blocking insulating pattern may cover the exposed top surfaces of the device isolation patterns.

In some example embodiments, a thickness of the oxidation prevention pattern may range from 50% to 150% of a width of the control gate structure in the first direction.

In some example embodiments, a thickness of the metal electrode pattern may range from 150% to 250% of the width of the control gate structure in the first direction.

In still another aspect, a semiconductor device may include a lower conductive layer on a substrate, a barrier layer on the lower conducive layer, a metal layer on the barrier layer, an oxidation prevention layer including nitrogen having a composition of 48 at % to 52 at % on the metal layer, and a capping layer including silicon oxide which is in contact with the oxidation prevention layer on the oxidation prevention layer.

### BRIEF DESCRIPTION OF THE FIGURES

Preferred embodiments will be described below in more detail with reference to the accompanying drawings, in which:

FIG. 1 is a cross sectional view illustrating a semiconductor device in accordance with example embodiments.

FIG. 2 is a top plan view illustrating a semiconductor device in accordance with example embodiments.

FIG. 3 is a cross sectional view taken along lines I-I′ and II-II′ of FIG. 2 to illustrate a semiconductor device in accordance with example embodiments.

FIGS. 4 through 12 are cross sectional views corresponding to the lines I-I′ and II-II′ of FIG. 2 to illustrate a method of manufacturing a semiconductor device in accordance with example embodiments.

FIG. 13 is a cross section view taken along the lines I-I′ and II-II′ of FIG. 2 to illustrate a semiconductor device in accordance with example embodiments.

FIG. 14 is a block diagram illustrating an example of a memory system including a semiconductor device in accordance with example embodiments.

FIG. 15 is a block diagram illustrating an example of an electronic system including a semiconductor device in accordance with example embodiments.

### DETAILED DESCRIPTION

Embodiments will be described more fully hereinafter with reference to the accompanying drawings. The embodiments may, however, be embodied in many different forms and should not be construed as limited to those set forth herein. Rather, these embodiments are provided so that this disclosure will be thorough and complete, and will fully convey the scope of the exemplary implementations to those skilled in the art. In the drawings, the size and relative sizes of layers and regions may be exaggerated for clarity. Like numbers refer to like elements throughout.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments may be described with reference to cross-sectional illustrations, which are schematic illustrations of idealized embodiments. As such, variations from the shapes of the illustrations, as a result, for example, of manufacturing techniques and/or tolerances, are to be expected. Thus, embodiments should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit.

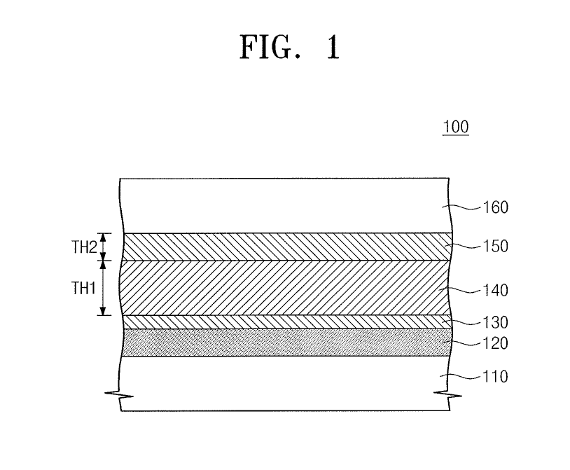

FIG. 1 is a cross sectional view illustrating a semiconductor device in accordance with example embodiments.

Referring to FIG. 1, a semiconductor device 100 may include a lower layer 120, a barrier metal layer 130, a metal electrode 140, an oxidation prevention layer 150 and a capping layer 160 that are sequentially stacked on a substrate 110.

The substrate 110 may be a semiconductor substrate. For example, the substrate 110 may be a single-crystalline silicon substrate, a silicon-germanium (SiGe) substrate, or a semiconductor-on-insulator (SOI) substrate.

The lower layer 120 may be provided on the substrate 110. The lower layer 120 may include a semiconductor material, a conductive material, or an insulating material. The lower layer 120 may be a single layer, or a multiple layer in which a plurality of layers is stacked. For example, the lower layer 120 may include a plurality of stacked insulating layers and may further include a conductive layer or a semiconductor layer between the stacked insulating layers. According to some embodiments, the lower layer 120 may include a poly-crystalline silicon layer as the conductive layer or the semiconductor layer. The lower layer 120 may be formed by performing, for example, a chemical vapor deposition (CVD) process, a physical vapor deposition (PVD) process, or an atomic layer deposition (ALD) process.

The barrier metal layer 130 may be provided on the lower layer 120. The barrier layer 130 may prevent metal atoms included in the metal electrode 140 from being diffused into the lower layer 120. The barrier metal layer 130 may include, for example, a conductive metallic nitride such as tungsten nitride (WN), molybdenum nitride (MoN), titanium nitride (TiN), or tantalum nitride (TaN). The barrier metal layer 130 may be formed by performing, for example, a chemical vapor deposition (CVD) process, a physical vapor deposition (PVD) process, or an atomic layer deposition (ALD) process.

The metal electrode 140 may be provided on the barrier metal layer 130. The metal electrode 140 may include tungsten (W). The metal electrode 140 may be formed by performing, for example, a chemical vapor deposition (CVD) process, a physical vapor deposition (PVD) process, or an atomic layer deposition (ALD) process.

The oxidation prevention layer 150 may be provided on the metal electrode 140. The oxidation prevention layer 150 may include a metallic nitride or a noble metal (e.g., gold). For example, the metallic nitride may include at least one of tungsten nitride, titanium nitride, and tantalum nitride. In the case that the oxidation prevention layer 150 includes the metallic nitride, a composition ratio of nitrogen included in the metallic nitride may range from about 48 at % to about 52 at %. A thickness TH2 of the oxidation prevention layer 150 may be smaller than a thickness TH1 of the metal electrode 140. The thickness TH2 of the oxidation prevention layer 150 may range from about 25% to about 75% of the thickness TH1 of the metal electrode 140. The oxidation prevention layer 150 may be formed by performing, for example, a chemical vapor deposition (CVD) process, a physical vapor deposition (PVD) process, or an atomic layer deposition (ALD) process.

The capping layer 160 may be provided on the oxidation prevention layer 150. The capping layer 160 may protect a lower structure disposed thereunder. The capping layer 160 may include silicon oxide. The capping layer 160 may be formed by performing a chemical vapor deposition (CVD) process. According to an example embodiment, the capping layer 160 may be formed by performing a plasma-enhanced chemical vapor deposition (PECVD) process using a reactive gas including tetraethoxysilane (TEOS) and at least one of oxygen (O₂) and nitrous oxide (N₂O).

In the semiconductor device 100 according to example embodiments, since the oxidation prevention layer 150 may include the metallic nitride or the noble metal, its reactivity with respect to oxygen may be low. Accordingly, the oxidation prevention layer 150 may prevent the metal electrode 140 from being oxidized in a subsequent process (for example, a process of forming the capping layer 160).

Further, since the oxidation prevention layer 150 includes the metallic nitride or the noble metal, its conductivity may be high. Accordingly, the oxidation prevention layer 150 may function as an electrode together with the meal electrode 140. Consequently, the electrode of the semiconductor device 100 may have a small thickness and a low sheet resistance, compared with an electrode of a semiconductor device including an oxidation prevention layer including an insulator (e.g., silicon nitride).

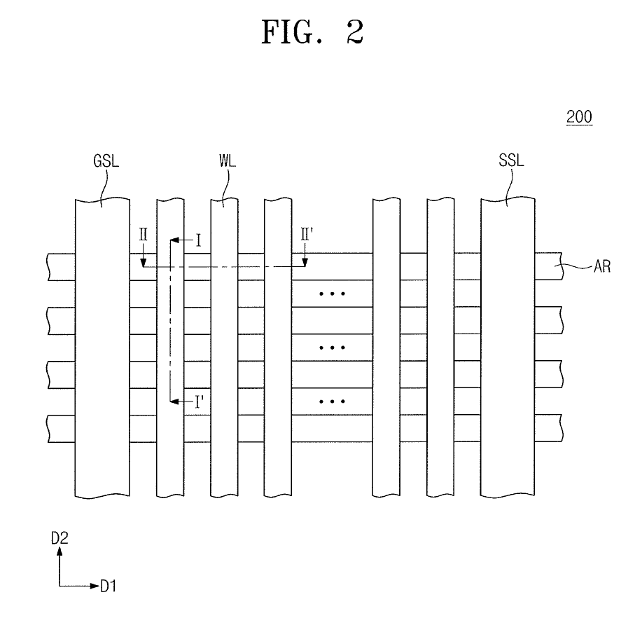

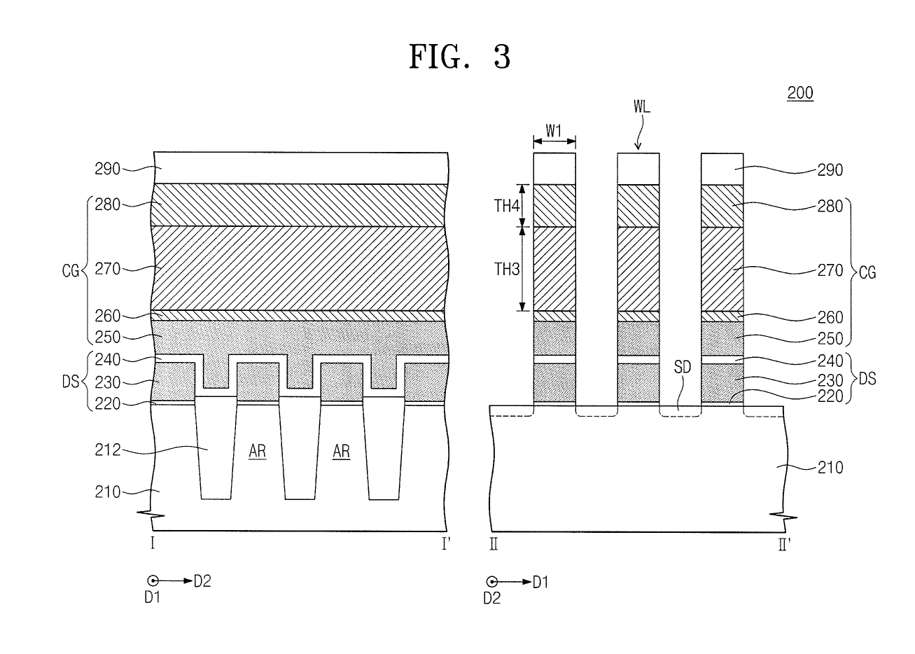

FIG. 2 is a top plan view illustrating a semiconductor device in accordance with example embodiments. FIG. 3 is a cross sectional view taken along the lines I-I′ and II-II′ of FIG. 2 to illustrate a semiconductor device in accordance with example embodiments.

Referring to FIGS. 2 and 3, a semiconductor device 200 may include active regions AR defined in a substrate 210. The active regions AR may extend in a first direction D1 and may be parallel to one another. A string selection line SSL and a ground selection line GSL may be provided on the active regions AR to cross over the active regions AR in a second direction D2 crossing the first direction D1. A plurality of word lines WL may be provided between the string selection line SSL and the ground selection line GSL to cross over the active regions AR. Each of the word lines WL may include an information storage structure DS, a control gate structure CG and a capping pattern 290.

The substrate 210 may be a semiconductor substrate. The substrate 210 may be a single-crystalline silicon substrate, a silicon-germanium (SiGe) substrate, or a semiconductor-on-insulator (SOI) substrate.

Device isolation patterns 212 may be provided in the substrate 210 to define the active regions AR. The device isolation patterns 212 may extend in the first direction D1 and may be parallel to one another. The device isolation patterns 212 may include, for example, silicon oxide. Each of the active regions AR may be a part of the substrate 210 between the device isolation patterns 212. Thus, each of the active regions AR may extend in the first direction D1. The active regions AR may be spaced apart from one another in the second direction D2. According to an embodiment, a liner nitride layer may be further provided between the substrate 210 and the device isolation patterns 212.

The information storage structure DS may be disposed on the substrate 210. The information storage structures DS may be spaced apart from one another in the first direction D1. A top surface of the substrate 210 may be exposed between the information storage structures DS. Source/drain regions SD may be provided in the substrate 210 exposed by the information storage structures DS. The source/drain regions SD may be impurity regions formed by implanting an n-type or p-type impurity into the substrate 210. The n-type impurity may be one of phosphorous, arsenic, bismuth and antimony. The p-type impurity may be boron.

Each of the information storage structures DS may include tunneling insulating patterns 220, charge storage patterns 230 on the tunnel insulating patterns 220, and a blocking insulating pattern 240 disposed on the charge storage patterns 230.

The charge storage patterns 230 of each of the information storage structures DS may be arranged along the second direction D2 so as to be disposed on the active regions AR, respectively. The charge storage patterns 230 of each of the information storage structures DS may be spaced apart from one another with the device isolation patterns 212 interposed therebetween. That is, when viewed from a top plan view, the charge storage patterns 230 may be disposed at crossing points of the active regions AR and the word lines WL, respectively. The charge storage patterns 230 may each include poly-crystalline silicon doped with an n-type or p-type impurity. The n-type impurity may be one of phosphorous, arsenic, bismuth and antimony. The p-type impurity may be boron.

Each of the tunneling insulating patterns 220 may be disposed between each of the charge storage patterns 230 and the substrate 210 and may electrically insulate each of the charge storage patterns 230 from the substrate 210. A thickness of each of the tunneling insulating patterns 220 may range from about 1 nm to about 10 nm. For example, the tunneling insulating patterns 220 may each include silicon oxide.

In each of the information storage structures DS, the blocking insulating pattern 240 may cover at least a part of sidewalls and an entire top surface of each of the charge storage patterns 230 and may extend in the second direction D2 to cover top surfaces of the device isolation patterns 212 between the charge storage patterns 230. The blocking insulating pattern 240 may include silicon oxide, silicon nitride, and/or a laminated structure thereof. The blocking insulating pattern 240 may be oxide-nitride-oxide (ONO) layer.

The control gate structure CG may be disposed on the information storage structure DS. The control gate structure CG may include a poly-crystalline silicon pattern 250, a barrier metal pattern 260, a metal electrode pattern 270, and an oxidation prevention pattern 280 which are sequentially stacked. In some example embodiments, a memory cell may be formed at a crossing point of each of the active regions AR and each of the control gate structures CG (e.g., word lines WL) and may include the tunnel insulating pattern 220, the charge storage pattern 230, the blocking insulating pattern 240, the control structure CG, and the source/drain regions SD,

The poly-crystalline silicon pattern 250 may be disposed between the blocking insulating pattern 240 and the barrier metal pattern 260. The poly-crystalline silicon pattern 250 may have a flat top surface. The poly-crystalline silicon pattern 250 may be electrically insulated from the charge storage patterns 230 by the blocking insulating pattern 240. The poly-crystalline silicon pattern 250 may include an n-type or p-type impurity. The n-type impurity may be one of phosphorous, arsenic, bismuth and antimony. The p-type impurity may be boron.

The barrier metal pattern 260 may be disposed between the poly-crystalline silicon pattern 250 and the metal electrode pattern 270. The barrier metal pattern 260 may prevent metal atoms included in the metal electrode pattern 270 from being diffused into the poly-crystalline silicon pattern 250. The barrier metal pattern 260 may include, for example, a conductive metallic nitride such as tungsten nitride (WN), molybdenum nitride (MoN), titanium nitride (TiN), or tantalum nitride (TaN).

The metal electrode pattern 270 may be disposed between the barrier metal pattern 260 and the oxidation prevention pattern 280. The metal electrode pattern 270 may include tungsten (W). A thickness TH3 of the metal electrode pattern 270 may range from about 150% to 250% of a width W1 of the control gate structure CG in the first direction D1. In an embodiment, the thickness TH3 of the metal electrode pattern 270 may be about twice the width W1 of the control gate structure CG in the first direction D1.

The oxidation prevention pattern 280 may be disposed on the metal electrode pattern 270. The oxidation prevention pattern 280 may include a metallic nitride or a noble metal (e.g., gold). For example, the metallic nitride may include at least one of tungsten nitride, titanium nitride, and tantalum nitride. In the case that the oxidation prevention pattern 280 includes the metallic nitride, a composition ratio of nitrogen included in the metallic nitride may range from about 48 at % to about 52 at %. A thickness TH4 of the oxidation prevention pattern 280 may range from about 50% to about 150% of the width W1 of the control gate structure CG in the first direction D1. The thickness TH4 of the oxidation prevention pattern 280 may be smaller than the thickness TH3 of the metal electrode pattern 270. The thickness TH4 of the oxidation prevention pattern 280 may range from about 25% to about 75% of the thickness TH3 of the metal electrode pattern 270.

The capping pattern 290 may be disposed on the control gate structure CG. That is, the control gate structure CG may be disposed between the information storage structure DS and the capping pattern 290. A width W1 of the capping pattern 290 in the first direction D1 may be substantially equal to the width W1 of the control gate structure CG in the first direction D1. The capping pattern 290 may include silicon oxide and may perform a function of protecting the control gate structure CG and the information storage structure DS.

In the semiconductor device 200 according to an example embodiment, since the oxidation prevention pattern 280 may include the metallic nitride or the noble metal, its reactivity with respect to oxygen may be low. Accordingly, the oxidation prevention pattern 280 may prevent the metal electrode pattern 270 from being oxidized in a subsequent process (for example, a process of forming the capping patterns 290).

Further, since the oxidation prevention pattern 280 includes the metallic nitride or the noble metal, its conductivity may be high. Accordingly, the oxidation prevention pattern 280 may function as the control gate structure CG together with the meal electrode pattern 270. Consequently, the control gate structure CG of the semiconductor device 200 may have a small thickness and a low sheet resistance, compared with a control gate structure of a semiconductor device including an oxidation prevention pattern including an insulator (e.g., silicon nitride). Accordingly, a whole thickness of the word line WL may be reduced and a phenomenon that the word line WL leans may be inhibited.

In an embodiment, a three dimensional (3D) memory array may be provided. The 3D memory array may be monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

In an embodiment, the 3D memory array may include vertical NAND strings that are vertically oriented such that at least one memory cell is located over another memory cell. The at least one memory cell may include a charge trap layer. Each vertical NAND string may include at least one select transistor located over memory cells, the at least one select transistor having the same structure with the memory cells and being formed monolithically together with the memory cells.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

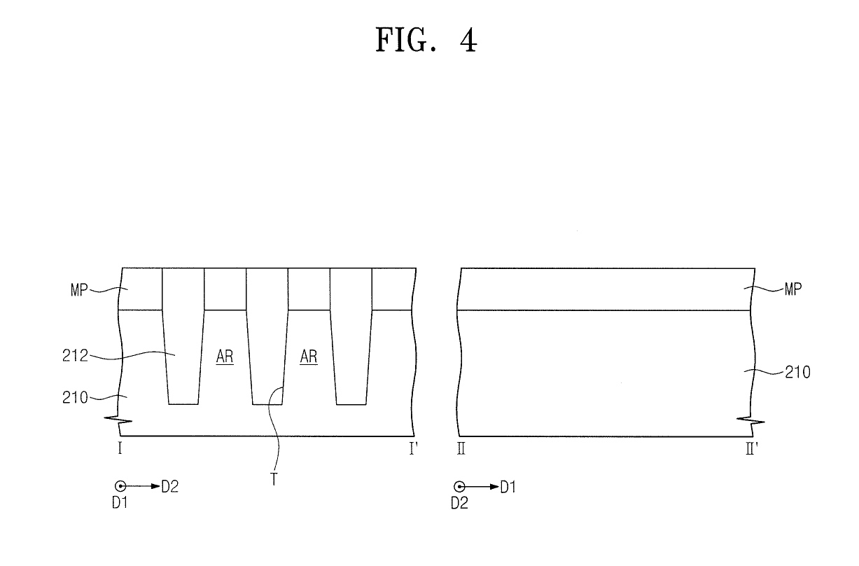

FIGS. 4 through 12 are cross sectional views corresponding to the lines I-I′ and II-II′ of FIG. 2 to illustrate a method of manufacturing a semiconductor device in accordance with example embodiments. Hereinafter, the same elements as described in the embodiment of FIGS. 2 and 3 will be indicated by the same reference numerals or the same reference designators. For the purpose of ease and convenience in explanation, the same descriptions as in the embodiment of FIGS. 2 and 3 will be omitted or mentioned briefly.

Referring to FIGS. 2 and 4, a substrate 210 may be provided. The substrate 210 may be a single-crystalline silicon substrate, a silicon-germanium (SiGe) layer, or a semiconductor-on-insulator (SOI) substrate.

Mask patterns MP may be formed on the substrate 210. Forming the mask patterns MP may include forming a mask layer on the substrate 210, and patterning the mask layer using a photolithography process. Each of the mask patterns MP may extend in a first direction D1. A top surface of the substrate 210 may be exposed by the mask patterns MP.

Trenches T defining active regions AR may be formed in the substrate 210. Forming the trenches T may include etching the substrate 210 using the mask patterns MP as an etching mask. Each of the trenches T may extend in the first direction D1.

Device isolation patterns 212 filling the trenches T and spaces between the mask patterns MP may be formed. The device isolation patterns 212 may include, for example, silicon oxide. Forming the device isolation patterns 212 may include forming a device isolation layer (not illustrated) filling the trenches T and spaces between the mask patterns MP and planarizing the device isolation layer to expose top surfaces of the mask patterns MP. The device isolation layer may be formed by performing, for example, a chemical vapor deposition (CVD) process, a physical vapor deposition (PVD) process, or an atomic layer deposition (ALD) process. According to some embodiments, before forming the device isolation patterns 212, a liner nitride layer may be formed to cover inner surfaces of the trenches T.

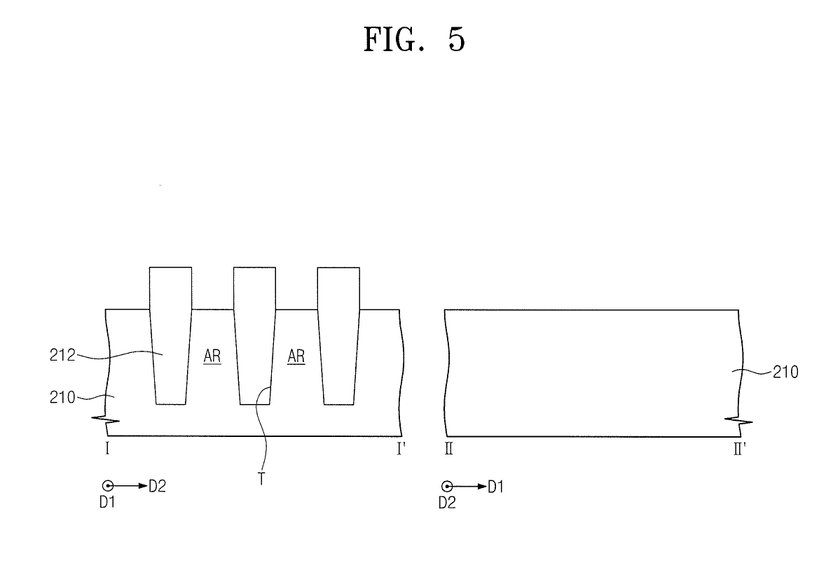

Referring to FIGS. 2 and 5, the mask patterns MP may be removed to expose the active regions AR. The mask patterns MP may be removed by, for example, a wet etching process.

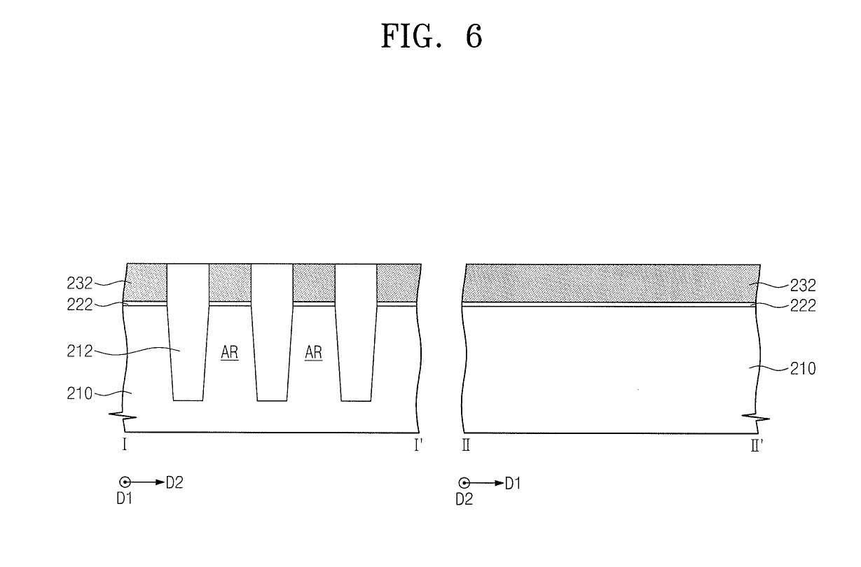

Referring to FIGS. 2 and 6, preliminary tunneling insulating patterns 222 may be formed on the exposed active regions AR. The preliminary tunneling insulating patterns 222 may extend in the first direction D1 and may be spaced apart from one another by the device isolation patterns 212. The preliminary tunneling insulating patterns 222 may be formed by, for example, performing a thermal oxidation process. The preliminary tunneling insulating patterns 222 may include, for example, silicon oxide. The preliminary tunneling insulating patterns 222 may be formed to have a thickness of about 1 nm to about 10 nm.

Preliminary charge storage patterns 232 may be formed on the preliminary tunneling insulating patterns 222. Each of the preliminary charge storage patterns 232 may fill a space between the device isolation patterns 212 and may extend in the first direction D1. The preliminary charge storage patterns 232 may be spaced apart from one another by the device isolation patterns 212. Forming the preliminary charge storage patterns 232 may include forming a charge storage layer filling spaces between the device isolation patterns 212 and planarizing the charge storage layer to expose top surfaces of the device isolation patterns 212. The charge storage layer may be formed by performing, for example, a chemical vapor deposition (CVD) process, a physical vapor deposition (PVD) process, or an atomic layer deposition (ALD) process. In an example embodiment, the preliminary charge storage patterns 232 may include poly-crystalline silicon doped with an n-type or p-type impurity. The n-type impurity may be one of phosphorous, arsenic, bismuth and antimony. The p-type impurity may be boron. The preliminary charge storage patterns 232 may be doped with the n-type or p-type impurity using an ion implanting method or an in-situ doping method.

Unlike this, according to an example embodiment, the mask patterns MP may include poly-crystalline silicon doped with the n-type or p-type impurity. Thus, the mask patterns MP may act as the preliminary charge storage patterns 232. In this case, the process of replacing the mask patterns MP with the preliminary charge storage patterns 232, which is described with reference to FIGS. 5 and 6, may be omitted. According to this embodiment, the preliminary tunneling insulating pattern may be formed on the substrate 210 before the mask patterns MP are formed.

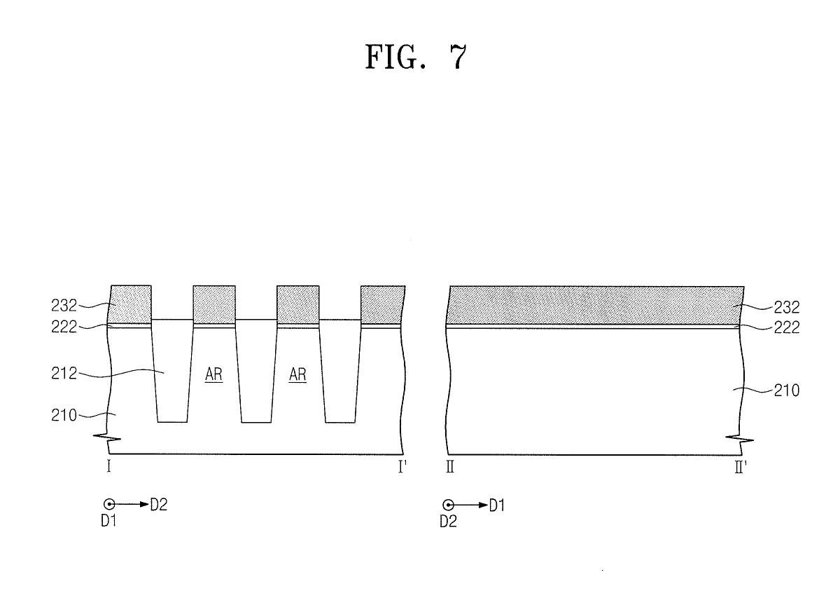

Referring to FIGS. 2 and 7, a part of the device isolation pattern 212 may be selectively recessed. The part of the device isolation pattern 212 may be recessed by, for example, an anisotropic etching process. Since the part of the device isolation pattern 212 is recessed, sidewalls of the preliminary charge storage patterns 232 may be exposed. Top surfaces of the recessed device isolation patterns 212 may be higher than top surfaces of the active regions AR.

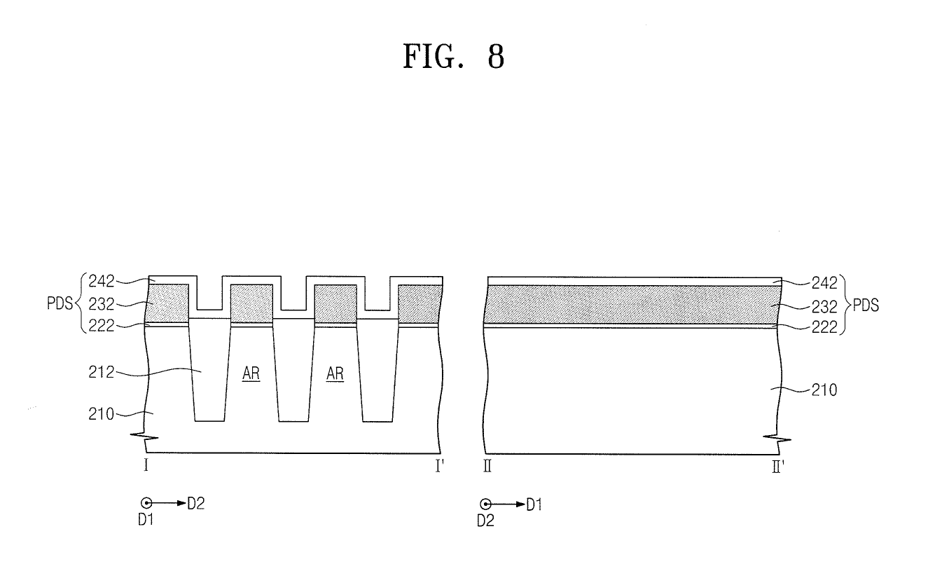

Referring to FIGS. 2 and 8, a blocking insulating layer 242 conformally covering the preliminary charge storage patterns 232 may be formed. The blocking insulating layer 242 may also cover the top surfaces of the device isolation patterns 212. The blocking insulating layer 242 may be formed by performing a chemical vapor deposition (CVD) process or an atomic layer deposition (ALD) process. The blocking insulating layer 242 may include silicon oxide, silicon nitride and/or a laminated structure thereof. The blocking insulating layer 242 may be an oxide-nitride-oxide (ONO) layer. The preliminary tunneling insulating patterns 222, the preliminary charge storage patterns 232 and the blocking insulating layer 242 which are sequentially stacked may be defined as a preliminary information storage structure PDS.

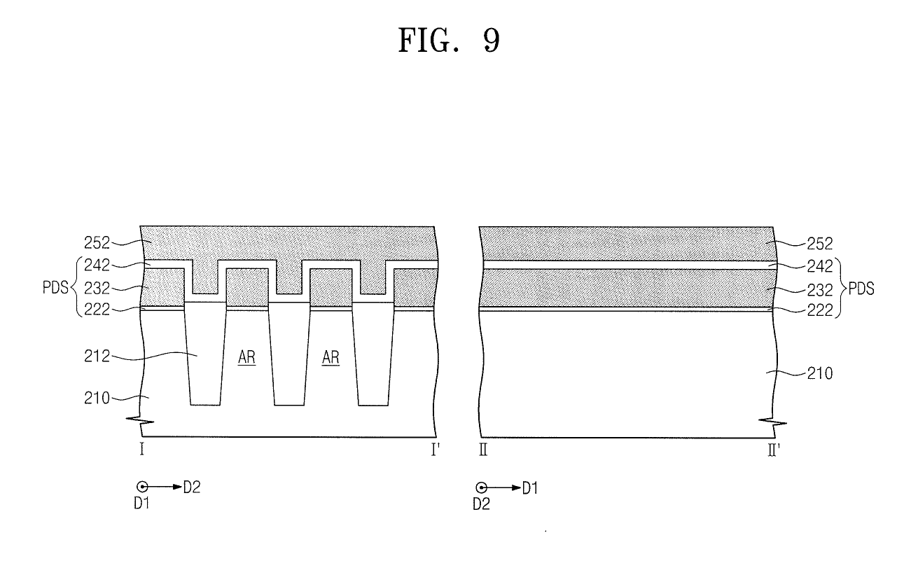

Referring to FIGS. 2 and 9, a poly-crystalline silicon layer 252 may be formed on the blocking insulating layer 242. The poly-crystalline silicon layer 252 may cover the blocking insulating layer 242 and may fill spaces between the preliminary charge storage patterns 232. The poly-crystalline silicon layer 252 may be formed by performing, for example, a chemical vapor deposition (CVD) process, a physical vapor deposition (PVD) process, or an atomic layer deposition (ALD) process. The poly-crystalline silicon layer 252 may include poly-crystalline silicon doped with an n-type or p-type impurity. The n-type impurity may be one of phosphorous, arsenic, bismuth and antimony. The p-type impurity may be boron. The polycrystalline silicon layer 252 may be doped with the n-type or p-type impurity using an ion implanting method or an in-situ doping method.

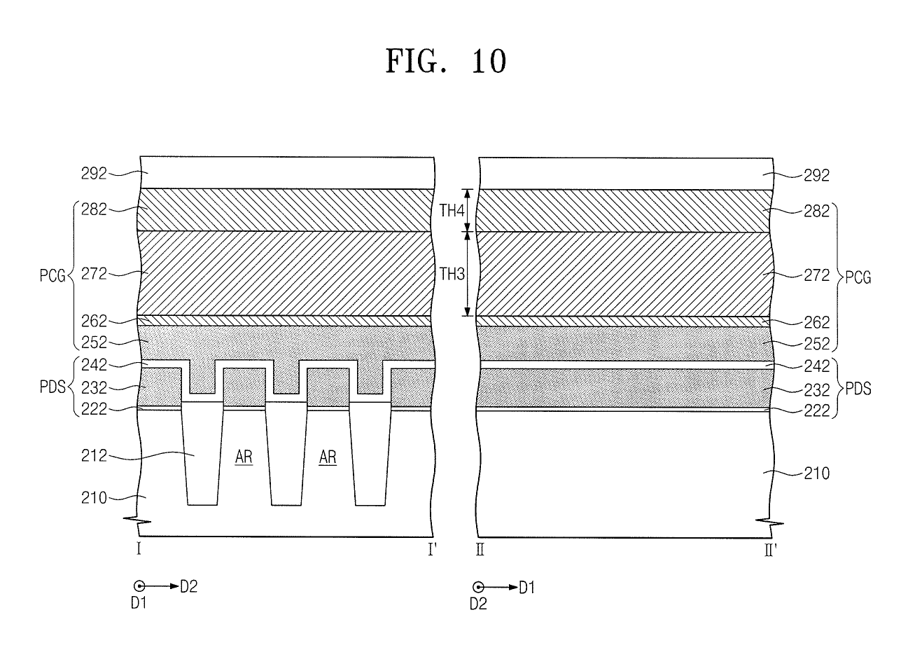

Referring to FIGS. 2 and 10, a barrier metal layer 262, a metal electrode layer 272, an oxidation prevention layer 282 and a capping layer 292 may be sequentially formed on the poly-crystalline silicon layer 252. Each of the barrier metal layer 262, the metal electrode layer 272, the oxidation prevention layer 282 and the capping layer 292 may be formed by performing, for example, a chemical vapor deposition (CVD) process, a physical vapor deposition (PVD) process, or an atomic layer deposition (ALD) process.

The barrier metal layer 262 may prevent metal atoms included in the metal electrode layer 272 from being diffused into the poly-crystalline silicon layer 252. The barrier metal layer 262 may include, for example, a conductive metallic nitride such as tungsten nitride (WN), molybdenum nitride (MoN), titanium nitride (TiN), or tantalum nitride (TaN).

The metal electrode layer 172 may include tungsten (W).

The oxidation prevention layer 282 may include a metallic nitride or a noble metal (for example, gold). For example, the metallic nitride may include at least one of tungsten nitride, titanium nitride, and tantalum nitride. Accordingly, reactivity of the oxidation prevention layer 282 with respect to oxygen may be low. In the case that the oxidation prevention layer 282 includes the metallic nitride, a composition ratio of nitrogen included in the metallic nitride may range from about 48 at % to about 52 at %. A thickness TH4 of the oxidation prevention layer 282 may be smaller than a thickness TH3 of the metal electrode layer 270. For example, the thickness TH4 of the oxidation prevention layer 282 may range from about 25% to about 75% of the thickness TH3 of the metal electrode layer 270.

The capping layer 292 may include silicon oxide. According to an example embodiment, the capping layer 292 may be formed by performing a plasma-enhanced chemical vapor deposition (PECVD) using a reactive gas including tetraethoxysilane (TEOS) and at least one of oxygen (O₂) and nitrous oxide (N₂O). During the process of forming the capping layer 292, the oxidation prevention layer 282 may prevent the metal electrode layer 272 from being oxidized.

The poly-crystalline silicon layer 252, the barrier metal layer 262, the metal electrode layer 272 and the oxidation prevention layer 282 that are sequentially laminated may be defined as a preliminary control gate structure PCG.

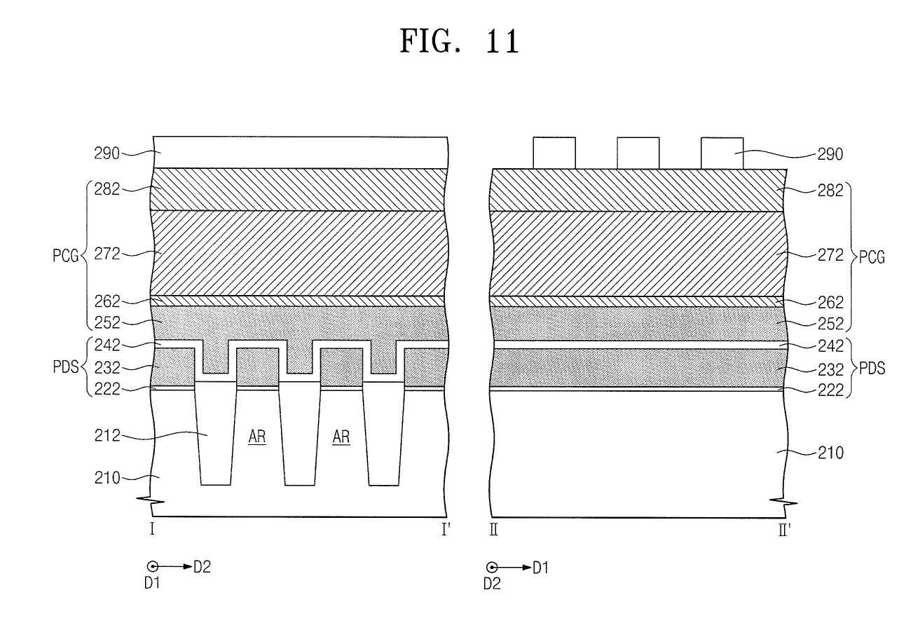

Referring to FIGS. 2 and 11, capping patterns 290 may be formed by patterning the capping layer 292. The formation the capping patterns 290 may include forming a photoresist layer on the capping layer 292, patterning the photoresist layer using a photolithography process to form photoresist patterns, and etching the capping layer 292 using the photoresist patterns as an etching mask. The capping patterns 290 may extend in a second direction D2 and may be spaced apart from one another in the first direction D1. Portions of a top surface of the oxidation prevention layer 282 may be exposed by the capping patterns 290.

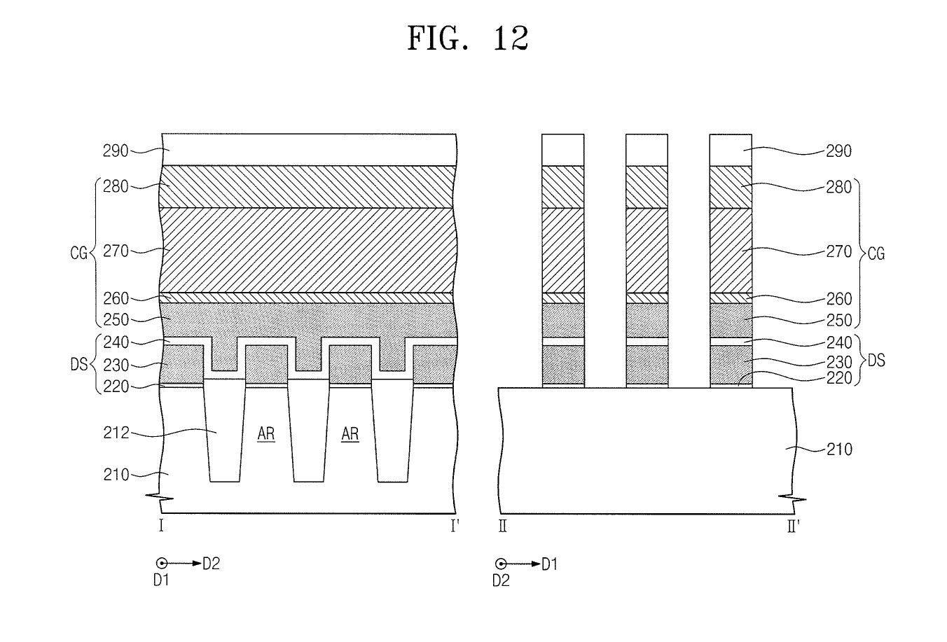

Referring to FIGS. 2 and 12, the preliminary information storage structure PDS and the preliminary control gate structure PCG may be patterned to form information storage structures DS and control gate structures CG. The information storage structures DS and the control gate structures CG may be formed by anisotropically etching the preliminary information storage structure PDS and the preliminary control gate structure PCG using the capping patterns 290 as an etching mask. The control gate structures CG may be located on the information storage structures DS, respectively. The control gate structures CG may extend in the second direction D2 and may be spaced apart from one another in the first direction D1. The information storage structures DS may be spaced apart from one another in the first direction D1. Each of the information storage structures DS may include tunneling insulating patterns 220, charge storage patterns 230 disposed on the tunnel insulating patterns 220, and a blocking insulating pattern 240 disposed on the charge storage patterns 230. The tunneling insulating patterns 220 and the charge storage patterns 230 of each of the information storage patterns DS may be disposed at crossing points of the active regions AR and the control gate structures CG (e.g., word lines WL), respectively. The blocking insulating pattern 240 may extend along the second direction D2. Each of the control gate structures CG may include a poly-crystalline silicon pattern 250, a barrier metal pattern 260, a metal electrode pattern 270 and an oxidation prevention pattern 280 that are sequentially stacked. A top surface of the substrate 210 may be exposed between the information storage structures DS.

Referring again to FIGS. 2 and 3, source/drain regions SD may be formed in an upper portion of the substrate 210 exposed by the information storage structures DS. The source/drain regions SD may be formed by implanting n-type or p-type impurity into the substrate 210. The n-type impurity may be one of phosphorous, arsenic, bismuth and antimony. The p-type impurity may be boron

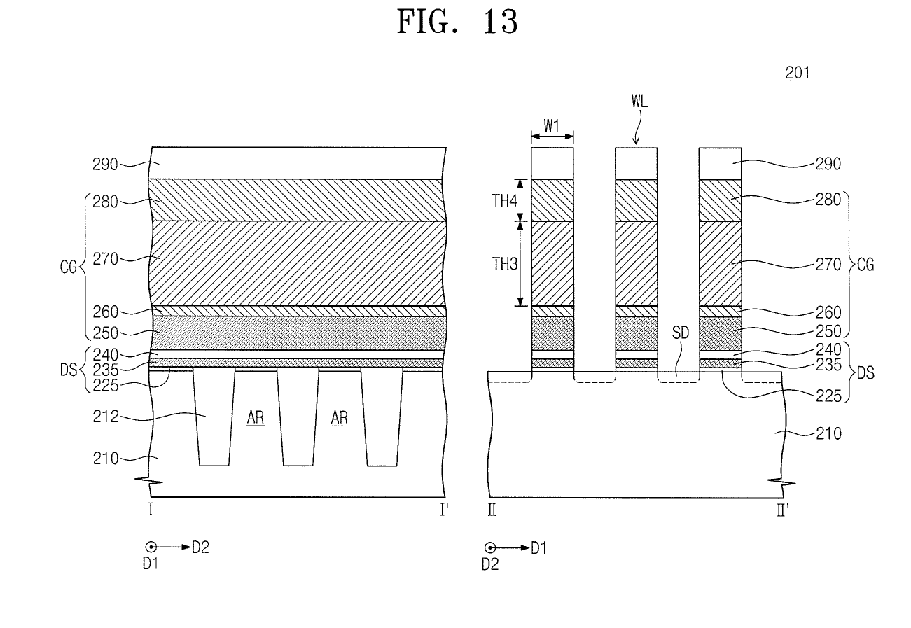

FIG. 13 is a cross section view taken along the lines I-I′ and II-II′ of FIG. 2 to illustrate a semiconductor device in accordance with example embodiments. Other elements of a semiconductor device 201 according to the present example embodiment except an information storage structure may be the substantially same as corresponding elements of the semiconductor device 200 described with reference to FIGS. 2 and 3. Hereinafter, the same elements as described in the embodiment of FIGS. 2 and 3 will be indicated by the same reference numerals or the same reference designators. For the purpose of ease and convenience in explanation, the descriptions to the same elements as in the embodiment of FIGS. 2 and 3 will be omitted or mentioned briefly.

Referring to FIGS. 2 and 13, an information storage structure DS may be disposed on a substrate 210. The plurality of information storage structures DS may extend in parallel to a second direction D2.

The information storage structure DS may include a tunneling insulating pattern 225, a charge storage pattern 235 and a blocking insulating pattern 240 that are sequentially laminated on the substrate 210.

The charge storage pattern 235 may extend in the second direction D2 while crossing device isolation patterns 212 and active regions AR. The charge storage pattern 235 may include silicon nitride.

The tunneling insulating pattern 225 may be disposed between the charge storage pattern 235 and the active regions AR and may electrically insulate the charge storage pattern 235 from the active regions AR. The tunneling insulating pattern 225 may include silicon oxide.

The blocking insulating pattern 240 may be provided on the charge storage pattern 235 to extend in the second direction D2. The blocking insulating pattern 240 may include a high-k dielectric material such as aluminum oxide or hafnium oxide.

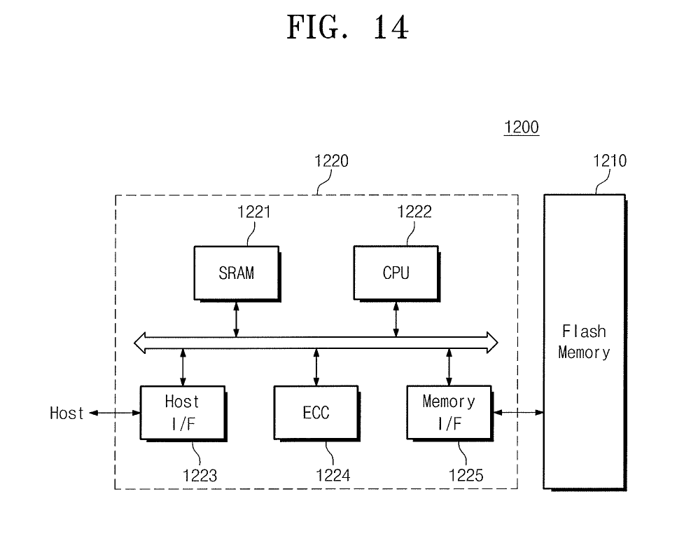

FIG. 14 is a block diagram illustrating an example of a memory system including a semiconductor device in accordance with example embodiments.

Referring to FIG. 14, a memory system 1200 includes a memory device 1210. The memory device 1210 may include at least one of the semiconductor devices disclosed in the aforementioned embodiments. The memory device 1210 may further include different types of semiconductor memory devices (e.g., a DRAM device and/or a SRAM device). The memory system 1200 may include a memory controller 1220 that controls a data exchange between a host and the memory device 1210. The memory device 1210 and/or the controller 1220 may include the semiconductor device in accordance with the example embodiments.

The memory controller 1220 may include a central processing unit (CPU) 1222 that controls an overall operation of the memory system 1200. The memory controller 1220 may include a SRAM 1221 being used as an operation memory of the central processing unit 1222. In addition, the memory controller 1220 may further include a host interface 1223 and a memory interface 1225. The host interface 1223 may include a data exchange protocol between the memory system 1200 and the host. The memory interface 1225 can connect the memory controller 1220 and the memory device 1210 to each other. The memory controller 1220 may further include an error correction circuit (ECC) 1224. The error correction circuit (ECC) can detect and correct an error of data read out from the memory device 1210. Although not illustrated, the memory system 1200 may further include a ROM device storing code data for an interface with the host. The memory system 1200 may be used as a portable data storage device. Unlike this, the memory system 1200 may be embodied by a solid state drive (SSD).

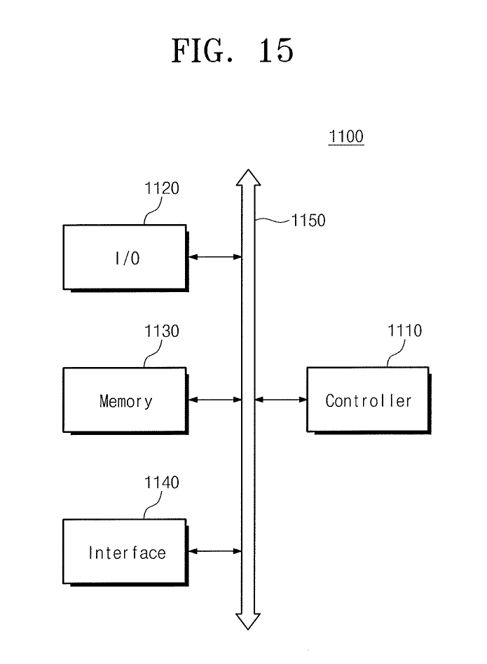

FIG. 15 is a block diagram illustrating an example of an electronic system including a semiconductor device in accordance with example embodiments.

Referring to FIG. 15, an electronic system 1100 in accordance with some example embodiments may include a controller 1110, an input/output (I/O) device 1120, a memory device 1130, an interface unit 1140 and a bus 1150. The controller 1110, the input/output (I/O) device 1120, the memory device 1130, and the interface unit 1140 may be combined with one another through the bus 1150. The bus 1150 corresponds to a path through which data are transmitted. The controller 1110, the input/output (I/O) device 1120, the memory device 1130, and/or the interface unit 1140 may include the semiconductor device in accordance with some example embodiments.

The controller 1110 may include at least one of a microprocessor, a digital signal process, a microcontroller, or logical device performing a function similar to any one thereof. The I/O device 1120 may include a keypad, a keyboard and/or a display device. The memory device 1130 may store data and/or commands. The interface unit 1140 may transmit data to a communication network and/or receive data from the communication network. The interface unit 1140 may operate by cable or wireless. The interface unit 1140 may include an antenna or a wire/wireless transceiver. Although not illustrated in the drawing, the electronic system 1100 may further include a fast DRAM device or a fast SRAM device which act as an operation memory device for improving an operation of the controller 1100.

The electronic system 1100 may be applied to a personal digital assistant (PDA), a portable computer, a web tablet, a mobile phone, a wireless phone, a digital music player, or other electronic products transmitting and/or receiving information data under a wireless environment.

According to the semiconductor device in accordance with some example embodiments, the oxidation prevention layer preventing oxidation of the metal electrode may include a conductive metallic nitride. Accordingly, the oxidation prevention layer can perform a function as an electrode together with the metal electrode and consequently, an electrode having a small thickness and a low resistance may be embodied.

Although a few embodiments have been shown and described, it will be appreciated by those skilled in the art that changes may be made in these embodiments without departing from the principles and spirit of the present disclosure, the scope of which is defined in the appended claims and their equivalents. Therefore, the above-disclosed subject matter is to be considered illustrative, and not restrictive.

What is claimed is:

1. A semiconductor device, comprising:
a charge storage pattern on a substrate;
a blocking insulating pattern on the charge storage pattern; and
a control gate structure on the blocking insulating pattern, the control gate structure including:
a metal electrode pattern, and
an oxidation prevention pattern on the metal electrode pattern, the oxidation prevention pattern including a metallic nitride.

2. The semiconductor device of claim 1, wherein the oxidation prevention pattern includes at least one of titanium nitride, tungsten nitride, and tantalum nitride.

3. The semiconductor device of claim 2, wherein a composition ratio of nitrogen in the oxidation prevention pattern ranges from 48 at % to 52 at %.

4. The semiconductor device of claim 1, wherein the metal electrode pattern includes tungsten.

5. The semiconductor device of claim 1, further comprising a capping pattern on the control gate structure, the capping pattern including silicon oxide.

6. The semiconductor device of claim 5, wherein the capping pattern is in contact with the oxidation prevention pattern.

7. The semiconductor device of claim 1, wherein the control gate structure further comprises:
a poly-crystalline silicon pattern between the metal electrode pattern and the blocking insulating pattern; and
a barrier metal pattern between the metal electrode pattern and the poly-crystalline silicon pattern.

8. The semiconductor device of claim 1, wherein a thickness of the oxidation prevention pattern is smaller than a thickness of the metal electrode pattern.

9. The semiconductor device of claim 1, further comprising a tunneling insulating pattern between the substrate and the charge storage pattern.

10. The semiconductor device of claim 1, wherein the oxidation prevention pattern is in contact with the metal electrode pattern.

11. A semiconductor device, comprising:
a substrate including active regions defined by device isolation patterns extending in a first direction, the active regions being spaced apart from one another in a second direction crossing the first direction;
a charge storage pattern on at least one of the active regions;
a blocking insulating pattern extending in the second direction to cover the charge storage pattern; and
a control gate structure on the blocking insulating pattern to extend in the second direction, the control gate structure including:
a metal electrode pattern, and
an oxidation prevention pattern on the metal electrode pattern, the oxidation prevention including a metallic nitride.

12. The semiconductor device of claim 11, wherein the oxidation prevention pattern includes at least one of titanium nitride, tungsten nitride, and tantalum nitride.

13. The semiconductor device of claim 12, wherein a composition ratio of nitrogen in the oxidation prevention pattern ranges from 48 at % to 52 at %.

14. The semiconductor device of claim 11, further comprising a capping pattern on the control gate structure to extend in the second direction, the capping pattern including silicon oxide.

15. The semiconductor device of claim 14, wherein the capping pattern is in contact with the oxidation prevention pattern.

16. The semiconductor device of claim 11, wherein the control gate structure further comprises:
a poly-crystalline silicon pattern between the metal electrode pattern and the blocking insulating pattern; and
a barrier metal pattern between the metal electrode pattern and the poly-crystalline silicon pattern.

17. The semiconductor device of claim 11, wherein:
the charge storage pattern includes a plurality of charge storage patterns on respective ones of the active regions and arranged in the second direction,
top surfaces of the device isolation patterns are exposed between the charge storage patterns, and
the blocking insulating pattern covers the exposed top surfaces of the device isolation patterns.

18. The semiconductor device of claim 11, wherein a thickness of the oxidation prevention pattern ranges from 50% to 150% of a width of the control gate structure in the first direction.

19. The semiconductor device of claim 18, wherein a thickness of the metal electrode pattern ranges from 150% to 250% of the width of the control gate structure in the first direction.

20. A semiconductor device, comprising:
a lower conductive layer on a substrate;
a barrier layer on the lower conducive layer;
a metal layer on the barrier layer;
an oxidation prevention layer on the metal layer, the oxidation prevention layer including nitrogen having a composition of 48 at % to 52 at %; and
a capping layer including silicon oxide on the oxidation prevention layer, the capping layer being in contact with the oxidation prevention layer.
